(19) United States
(12) Patent Application Publication
(10) Pub. No.: US 2011/0070490 A1
(43) Pub. Date: Mar. 24, 2011

(54) CARBON ELECTRODES FOR ELECTROCHEMICAL APPLICATIONS

(75) Inventors: Benjamin Y. Park, Irvine, CA (US); Marc J. Madou, Irvine, CA (US)

(73) Assignee: The Regents of the University of California

(21) Appl. No.: 12/955,233

(22) Filed: Nov. 29, 2010

Related U.S. Application Data
(62) Division of application No. 11/624,967, filed on Jan. 19, 2007.

(51) Int. Cl. H01M 4/60; H01M 4/583; H01B 13/00; G03F 7/20

(52) U.S. Cl. 429/213; 429/231.8; 216/13

(57) ABSTRACT

Systems and methods are provided for producing high-surface-area three-dimensional electrodes for electrochemical applications. In one embodiment, sheets of precursor material are interleaved with sheets of a sacrificial material and then bonded to a base comprising a precursor material with a precursor bonding material. The precursor sheets, base and bonding material preferably formed from the same precursor material. The bonded structure is then pyrolyzed to create a lithium intercalating structure and remove the sacrificial material. In another embodiment, a reactive-ion etching process is used to pattern 3D structures into a sheet of precursor material. The 3D structure is then converted into a lithium intercalating structure through pyrolysis. In both embodiments, the components of the structure to be heat treated preferably comprise the same lithium intercalating precursor material. As a result, micro-scale high-aspect-ratio 3D electrode features having very fine structures can be patterned and created.

### CROSS-REFERENCE TO RELATED APPLICATION

This application is a divisional application of co-pending application Ser. No. 11/624,967 filed Jan. 19, 2007, which application is fully incorporated herein.

### FIELD OF THE INVENTION

The present invention relates to electrodes for electrochemical applications and, more particularly, to systems and methods for producing high-surface-area three-dimensional electrodes for electrochemical applications.

### BACKGROUND OF THE INVENTION

Highly ordered graphite as well as hard and soft carbons are used extensively as the negative electrodes of commercial Lithium (Li) ion batteries. The high energy density values reported for these Li batteries are generally based on the performance of larger cells with capacities of up to several ampere-hours. For small microbatteries, with applications in miniature portable electronic devices, such as cardiac pacemakers, hearing aids, smart cards and remote sensors, the achievable power and energy densities do not scale favorably because packaging and internal battery hardware have a greater effect on the overall size and mass of the completed battery. One approach to overcome the size and energy density deficiencies in current two dimensional (2D) microbatteries is to develop three dimensional (3D) battery architectures based on specially designed arrays composed of high aspect ratio three dimensional (3D) electrode elements. For example, a micro 3D battery which has electrode arrays with a 50:1 aspect ratio (height /width), the expected capacity may be 3.5 times higher and the surface area 350 times higher than for a conventional 2D battery design. The key challenge, however, in fabricating 3D microbatteries based is in achieving high aspect ratio electrodes to ensure a dramatic improvement in surface-to-volume ratio without a corresponding increase in overall volume and providing a reduced footprint, e.g., less than one cm², without compromising capacity. It is, however, very expensive and difficult to create 3D electrodes with high surface area.

Accordingly, it would be desirable to provide improved systems and methods for producing 3D electrodes with high surface area.

### SUMMARY OF THE INVENTION

The various embodiments and examples provided herein are generally directed to systems and methods for producing 3D electrodes with high surface area. In one embodiment, which is described below as an example only and not to limit the invention, sheets of a precursor material are integrated with sheets of a sacrificial material, wherein the sheets of the sacrificial material act as spacers interleaved with the sheets of the precursor material to form a sandwich structure. The precursor material when pyrolyzed preferably transforms into a lithium intercalating material such as carbon or carbon containing materials such as, e.g., carbon-silicon compounds and the like. For polymer based precursor materials, the material may comprise a single polymer material or a mixture of two or more polymers (polymer-precursor). A preferred type of polymer material for use as a polymer-precursor is a polyimide such as, e.g., Kapton®, Cirlex® or the like.

The sandwich structure is preferably bonded to a base preferably comprising a precursor material using a bonding material that is preferably a precursor material in liquid form. The precursor material of the sheets, base and bonding liquid preferably and advantageously comprise the same material. The bonded structure is then pyrolyzed to create a structure comprising a lithium intercalating material. The spacers, which preferably comprise paraffin or some other sacrificial material, are removed or evaporated during the pyrolysis process creating empty spaces or voids between the lithium intercalating sheets or walls. No other step other than pyrolysis needs to be done after the bonding of the materials. The bonding liquid used to bond the sandwich structure to the base preferably hardens and, carbonizes during the pyrolysis process while the sacrificial material (e.g. paraffin) is removed or evaporates.

In another embodiment, which is described below as an example only and not to limit the invention, a reactive-ion etching process (RIE), e.g. deep anisotropic inductive coupled plasma etching, is used to pattern 3D structures into a precursor sheet of material that when pyrolyzed transforms into an a lithium intercalating material. The precursor sheet is preferably formed from a polymer or mixture of two or more polymers preferably comprising a polyimide type of polymer. The 3D structure is then converted through pyrolysis into a lithium intercalating structure such as carbon or carbon containing material.

An advantageous aspect of both embodiments is that the entire structure to be heat treated is preferably formed from the same precursor material, which eliminates concerns regarding different thermal expansion and contraction rates corresponding to dissimilar materials during the heat treatment process. As a result, micro-scale high-aspect-ratio (e.g., aspect ratios≧300) 3D features having very fine structures (e.g., structures<10 microns) can be patterned and created. The resulting carbon containing structure can be used as an electrode for electrochemical applications. Unlike previous methods, e.g., methods using SU-8 to create carbon structures, polyimide yields a soft carbon which (in most cases) is a better material for use as a Li intercalating anode. Additionally, the polyimide can be converted into graphite at higher temperatures.

Further systems, methods, features and advantages of the invention will be or will become apparent to one with skill in the art upon examination of the following figures and detailed description. It is intended that all such additional systems, methods, features and advantages be included within this description, be within the scope of the invention, and be protected by the accompanying claims. It is also intended that the invention is not limited to the details of the example embodiments.

### BRIEF DESCRIPTION OF THE DRAWINGS

The details of the invention, both as to its structure and operation, may be gleaned in part by study of the accompanying figures, in which like reference numerals refer to like parts. The components in the figures are not necessarily to scale, emphasis instead being placed upon illustrating the principles of the invention. Moreover, all illustrations are intended to convey concepts, where relative sizes, shapes and other detailed attributes may be illustrated schematically rather than literally or precisely.

FIGS. 1A, 1B, 1C, 1D and 1E are schematics showing the fabrication process for producing 3D electrodes with high surface area in accordance with one embodiment.

FIG. 2 is a flow diagram showing the fabrication process depicted in FIG. 1.

FIGS. 3A, 3B, 3C, 3D, 3E and 3F are schematics showing the fabrication process for producing 3D electrodes with high surface area in accordance with another embodiment.

FIG. 4 is a flow diagram showing the fabrication process depicted in FIG. 3.

FIG. 5 is a flow diagram showing the fabrication process for producing a battery.

### BRIEF DESCRIPTION OF THE INVENTION

Each of the additional features and teachings disclosed below can be utilized separately or in conjunction with other features and teachings to provide 3D electrodes with high surface area and processes to form the same. Representative examples of the present invention, which examples utilize many of these additional features and teachings both separately and in combination, will now be described in further detail with reference to the attached drawings. This detailed description is merely intended to teach a person of skill in the art further details for practicing preferred aspects of the present teachings and is not intended to limit the scope of the invention. Therefore, combinations of features and steps disclosed in the following detail description may not be necessary to practice the invention in the broadest sense, and are instead taught merely to particularly describe representative examples of the present teachings.

Moreover, the various features of the representative examples and the dependent claims may be combined in ways that are not specifically and explicitly enumerated in order to provide additional useful embodiments of the present teachings. In addition, it is expressly noted that all features disclosed in the description and/or the claims are intended to be disclosed separately and independently from each other for the purpose of original disclosure, as well as for the purpose of restricting the claimed subject matter independent of the compositions of the features in the embodiments and/or the claims. It is also expressly noted that all value ranges or indications of groups of entities disclose every possible intermediate value or intermediate entity for the purpose of original disclosure, as well as for the purpose of restricting the claimed subject matter.

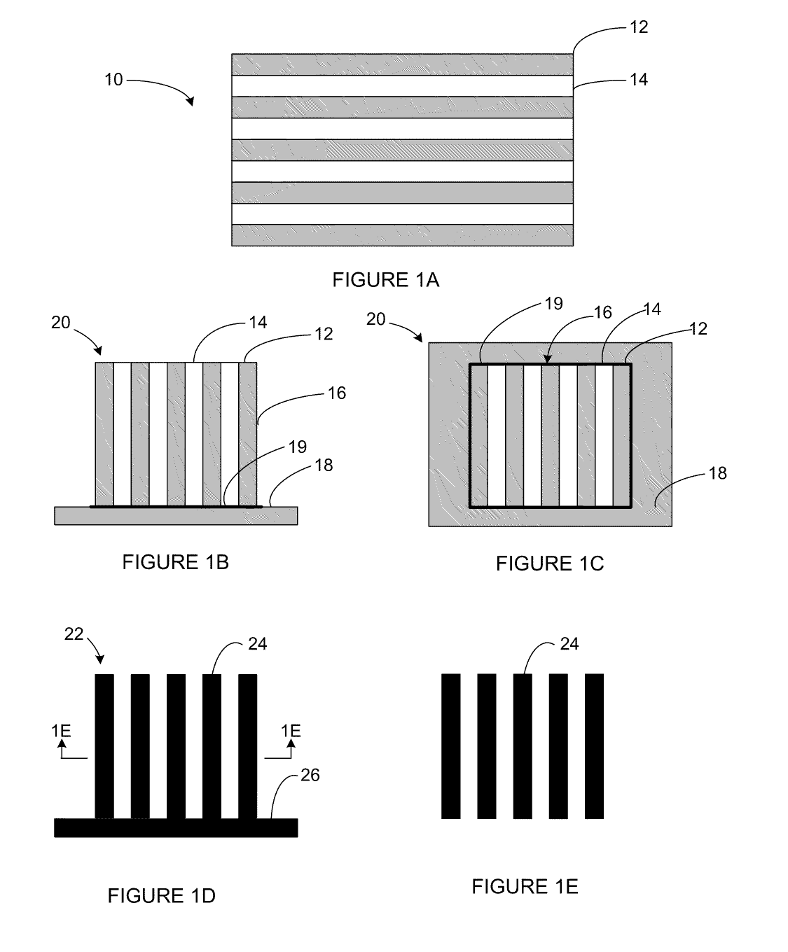

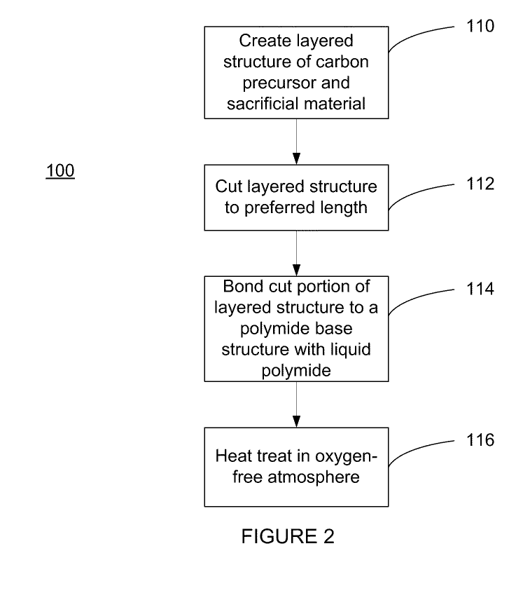

The various embodiments provided herein are generally directed to systems and methods for producing 3D electrodes with high surface area or high-aspect ratios. In one embodiment, as depicted in FIGS. 1A through 2, sheets of a precursor material are bonded, in a substrate-less process 100, to a base preferably comprising the same precursor material using a bonding material preferably comprising the same precursor material in liquid form to advantageously and preferably form a structure wherein the entire structure comprises the same precursor material. Use of the same material or mixture of material eliminates concerns about different thermal expansion or thermal contraction rates between dissimilar materials during the heat-treatment process.

At step 110 of the process 100, sheets of a precursor material 12 are interleaved with sheets of a sacrificial material 14 to create a layered, sandwich structure 10. The sheets 14 of sacrificial material preferably evaporate during the pyrolysis process creating a void between pyrolyzed precursor sheets 12. As shown in FIG. 1A, sheets of a precursor material 12 and a sacrificial material 14 are placed one on top of the other to create a layered sandwich structure 10. This can be done using thin sheets of any material that when pyrolyzed transforms into a lithium intercalating material such as carbon or a carbon containing material such as, e.g., a carbon-silicon compound, along with thin sheets of any sacrificial material that can be removed during the pyrolysis process. Carbon-precursor materials can comprise a single polymer, a mixture of two or more polymers or other carbon-precursors. A preferred polymer precursor material is a polyimide material such as, e.g., Kapton®, Cirlex® or the like, while the sacrificial material is preferably paraffin or some other sacrificial material that preferably evaporates during the pyrolysis process.

Next, at step 112, the layered structured 10 is sliced or cut to a predetermined length. The cut portion 16 of the layered structure is bonded, at step 114, to a base structure 18, preferably formed from the same precursor material as the precursor sheets 12. FIGS. 1B and 1C provide front and top views, respectively, of the bonded structure 20. Although shown to be uniform in shape, size and thickness, the individual precursor sheets 12 can vary in size, shape or thickness to accommodate varying battery designs.

The cut portion 16 of the sandwich structure 10 is preferably bonded to the base 18 using a bonding material 19 that preferably comprises the same precursor material as the percursor sheets 12 and base 18, and preferably in a liquid form. A preferred precursor bonding material is a polyimide material such as, e.g., P15878G. As a result, the entire structure after heat treatment is preferably comprised of lithium intercalating material such as carbon or other carbon containing material, thus enabling efficient current collection.

The entire bonded structure 20 is heated treated at step 116 to high temperatures (e.g., about 900° C. to 1500° C.) in an oxygen-free atmosphere and converted to a lithium intercalating material. The liquid bonding material preferably hardens at the lower temperatures and gets converted into a lithium intercalating material at higher temperatures. The polymer precursor sheets 12 and base 18 are transformed to a lithium intercalating material during the process forming a structure 22 comprising conductive fingers or walls 24 and base 26 as shown in FIGS. 1D and 1E. The sacrificial material (e.g. paraffin) 14 is evaporated during the process leaving voids 28 between the adjacent conductive walls or fingers 24.

In one experimental example, a polyimide-paraffin sandwich structure was formed by interleaving polyimide sheets with paraffin sheets. The sandwich structure was cut and bonded to a polyimide sheet or base using a polyimide liquid bonding material. During the heat-treatment process, the paraffin or sacrificial material between the polyimide sheets or walls evaporated leaving a void there between. The resulting carbonized structure was comprised of high aspect ratio walls extending from a base. The carbonized walls were approximately 3 mm tall and approximately 10 um thick, which corresponds to an aspect ratio of approximately 300. Thus, ultra-high aspect ratio electrodes are achievable using this method.

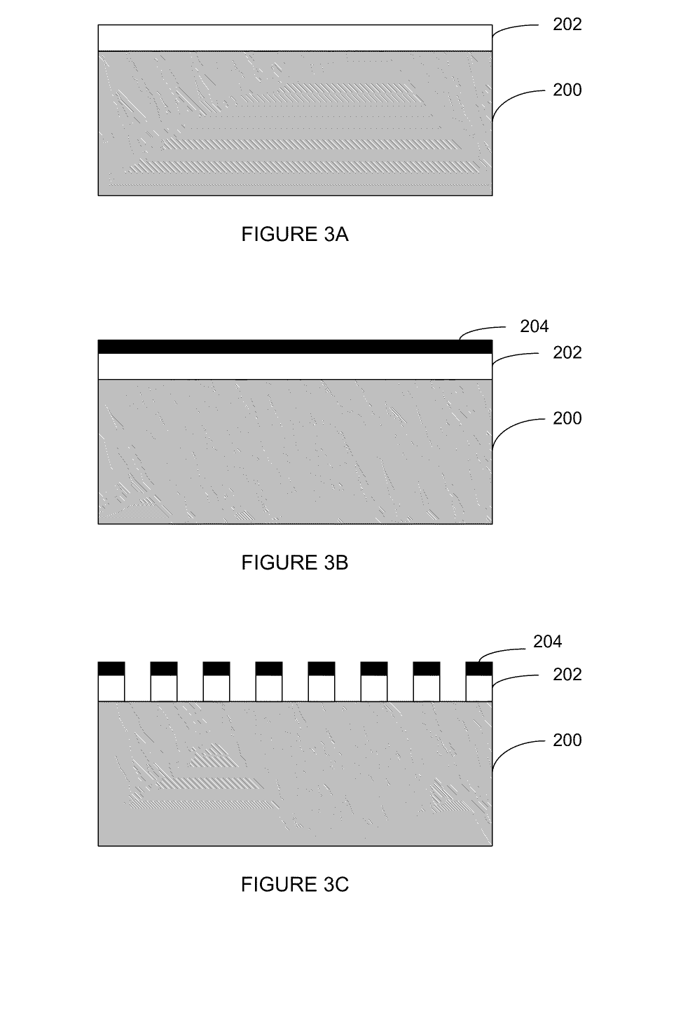

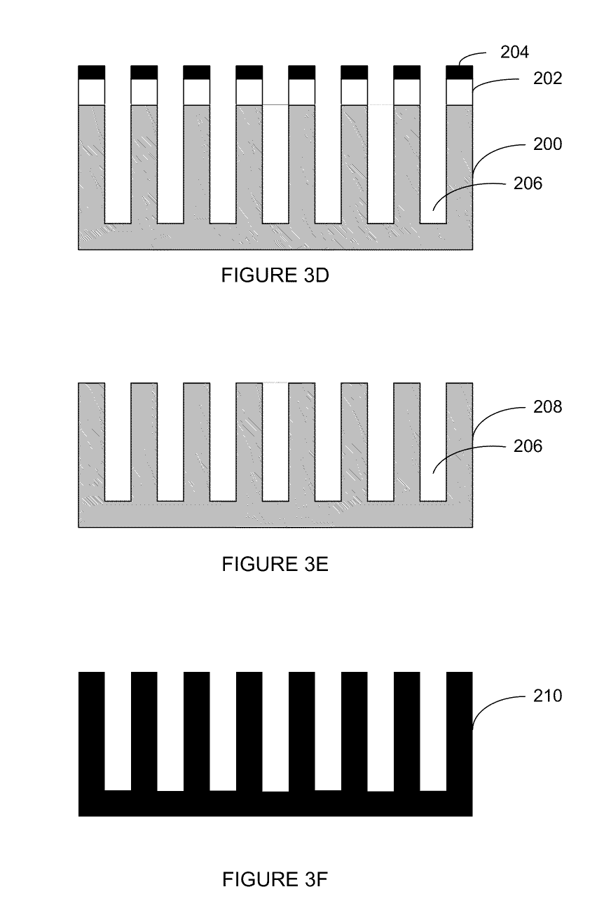

In another embodiment, as depicted in FIGS. 3a through 4, a reactive-ion etching process (RIE) 300, e.g. deep anisotropic inductive coupled plasma etching, is used to pattern 3D structures into a precursor sheet of material that when pyrolyzed transforms into an a lithium intercalating material. The precursor sheet is preferably formed from a polymer or mixture of two or more polymers preferably comprising a polyimide type of polymer. The 3D structure is then converted through pyrolysis into a lithium intercalating structure such as a carbon or carbon containing structure.

At step 310 of the process 300, a layer of photoresist 202 is deposited, as shown in FIG. 3A, on a sheet of a polymer-precursor material 200 such as a polyimide, e.g., Kapton®, Cirlex® or the like. The photoresist 202 is exposed and developed at step 320. In step 330, an RIE mask material 204 comprising a metal such as, e.g., Ti or Al, is deposited on top of the photoresist 202, as shown in FIG. 3B. As shown in FIG. 3C, the mask material 204 is patterned at step 340 preferably using a lift-off technique wherein the photoresist to which the metal is adhered is stripped along with the metal. At step 350, an RIE process is used to etch patterns or deep voids 206 into the polymer-precursor sheet 200 as shown in FIG. 3D. The remaining mask 204 and photoresist 202 material are removed at step 360 by conventional means. At step 370, the patterned polymer-precursor structure 208 shown in FIG. 3E is converted into a lithium intercalating structure 210 shown in FIG. 3F wherein the entire structure is conductive.

In both embodiments, the structure to be pyrolyzed can advantageously comprise a single type of pre-cursor material that transforms into a lithium intercalating material when pyrolyzed. As a result, micro-scale ultra high-aspect-ratio (e.g., aspect ratios≧300) 3D carbon features having very fine structures (e.g., structures <10 microns thick) can be patterned and created. The resulting carbon containing structure can be used as an electrode for electrochemical applications. Additionally, polyimide material can be converted into graphite at higher temperatures.

The resulting carbon containing structure can also be used as an anode in a Li-ion battery. Unlike previous methods, e.g., methods using SU-8 to create carbon structures, polyimide yields a soft carbon which (in most cases) is a better material for use as a Li intercalating anode. Experiments conducted on thin films of pyrolyzed Kapton®, which were heat treated at 900° C. and at 1500° C., confirmed that these films do intercalate Li ions.

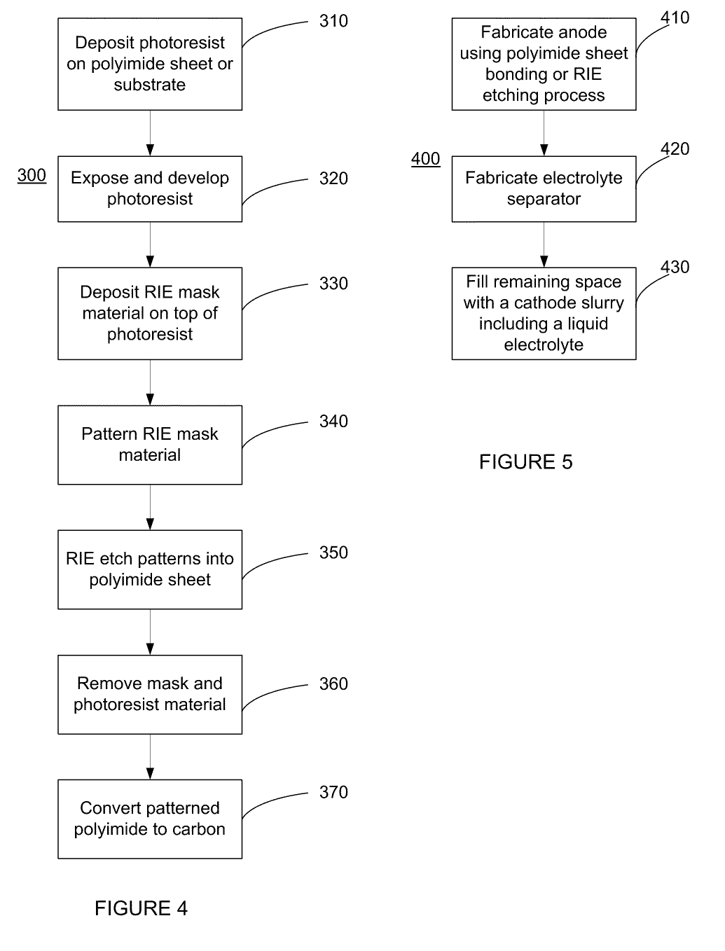

Turning to FIG. 5, a process 400 for creating a Li-ion battery is provided. At step 410, the anode of the battery is preferably fabricated using either of the processes described above. An electrolyte separator is fabricated at step 420. A fabrication method described in U.S. provisional application No. 60/837,657, which is incorporated herein by reference, can be used to create the electrolyte separator. In step 430, a cathode slurry including a liquid electrolyte can be used to fill in the remaining space within a containing structure to create a complete battery.

While the invention is susceptible to various modifications and alternative forms, a specific example thereof has been shown in the drawings and is herein described in detail. It should be understood, however, that the invention is not to be limited to the particular form disclosed, but to the contrary, the invention is to cover all modifications, equivalents, and alternatives falling within the spirit of the disclosure. Furthermore, it should also be understood that the features or characteristics of any embodiment described or depicted herein can be combined, mixed or exchanged with any other embodiment.

What is claimed:

1. A three dimensional carbon containing electrode comprising
a base comprising a carbon containing material, and
a plurality of fingers comprising a carbon containing material, wherein adjacent fingers are in spaced relation and the plurality of fingers extend outwardly from the base, and wherein the base and plurality of fingers are formed from the same carbon precursor material.

2. The electrode of claim 1 wherein the carbon precursor material comprises one or more polymers.

3. The electrode of claim 2 wherein the polymer material is a polyimide.

4. The electrode of claim 1 wherein the plurality of fingers are bonded to the base with a carbon containing bonding material and wherein bonding material is formed from the same carbon precursor material as the base and the plurality of fingers.

5. The electrode of claim 4 wherein the carbon precursor material comprises one or more polymers.

6. The electrode of claim 5 wherein the polymer material is a polyimide.

7. A method of forming a three dimensional carbon electrode comprising the steps of
depositing a layer of photoresist material on a layer of precursor material,
exposing and developing the layer of photoresist material,
depositing a layer of etching mask material on the layer of photoresist material,
patterning the layer of mask material by removing a portion of the mask material and the photoresist material to which the mask material is adhered,
etching voids within the layer of precursor material,
removing the remaining mask material and photoresist, and pyrolyzing the patterned layer of precursor material.

8. The method of claim 7 wherein the pyrolyzing step includes transforming the precursor materials into lithium intercalating material.

9. The method of claim 7 wherein the pyrolyzing step includes transforming the precursor materials into conductive carbon containing material.

10. The method of claim 7 wherein the precursor material comprises one or more polymers.

11. The method of claim 10 wherein the polymer material is a polyimide.

12. The method of claim 7 wherein the mask material is a metal.

13. The method of claim 12 wherein the metal is Ti or Al.

14. The method of claim 7 wherein the etching step comprises reactive-ion etching process.
